(19) United States
(12) Patent Application Publication
(10) Pub. No.: US 2025/0264521 A1
(43) Pub. Date: Aug. 21, 2025

(54) DETERMINING A QUALITY OF A CONNECTION BETWEEN A TEST SYSTEM AND A DEVICE UNDER TEST

(71) Applicant: LitePoint Corporation, San Jose, CA (US)

(72) Inventors: Chen Cao, Shanghai (CN); Christian Volf Olgaard, Saratoga, CA (US); Ruizu Wang, San Jose, CA (US); Qingjie Lu, Shanghai (CN)

(73) Assignee: LitePoint Corporation, San Jose, CA (US)

(21) Appl. No.: 18/593,279

(22) Filed: Mar. 1, 2024

(30) Foreign Application Priority Data
Feb. 20, 2024 (CN) 202410189964.9

(51) Int. Cl. G01R 31/28

(52) U.S. Cl. CPC G01R 31/2834; G01R 31/2822

(57) ABSTRACT

An example system includes a tester configured to test a device under test (DUT) and a connection setup that is connectable to, and disconnectable from, the DUT. The tester is configured to transmit radio frequency (RF) signals over the connection setup and to capture reflected signals from the connection setup. The reflected signals are based on the RF signals. One or more processing devices are configured to use a trained machine learning model to determine a quality of a connection between the test system and the DUT based on the reflected signals.

### TECHNICAL FIELD

This specification describes example implementations of techniques for determining a quality of a connection between a test system and a device under test.

### BACKGROUND

A test system is configured to test the operation of a device. A device tested by the test system is referred to as a device under test (DUT). The test system may include test instruments to send test signals, such as radio frequency (RF) signals, and data over a transmission medium, such as an RF transmission line or coaxial cable, to the DUT for testing. The test system may also test the quality of the connection between the test system and the DUT, since connection quality will affect test results.

### SUMMARY

An example system includes a tester configured to test a device under test (DUT) and a connection setup that is connectable to, and disconnectable from, the DUT. The tester is configured to transmit radio frequency (RF) signals over the connection setup and to capture reflected signals from the connection setup. The reflected signals are based on the RF signals. One or more processing devices are configured to use a trained machine learning model to determine a quality of a connection between the test system and the DUT based on the reflected signals. The example system may include one or more of the following features, either alone or in combination.

The tester may be configured to capture first data when the connection setup is disconnected from the DUT. The first data may be based on first ones of the reflected signals. The tester may be configured to capture second data when the connection setup is connected to the DUT. The second data may be based on second ones of the reflected signals. The second ones of the reflected signals may each be associated with a respective return loss. The respective return loss may include a return loss contribution from the DUT. Determining the quality of the connection may include determining a return loss of the connection setup when the connection setup is connected to the DUT minus the return loss contribution from the DUT.

The one or more processing devices may be configured to process data based on the reflected signals in the first data and the second data to remove a return loss contribution from the tester. Following processing, the one or more processing devices may be configured to resample data based on the reflected signals in the first data and the second data. Following resampling, the one or more processing devices may be configured to filter data based on the reflected signals in the first data and the second data to attenuate representations of the reflected signals in the first data and the second data. Following filtering, the one or more processing devices may be configured to process data based on the reflected signals in the first data and the second data to discount, in each signal, a path loss associated with the connection setup and thereby produce combined data. The combined data may include magnitude data and phase data that is based on the reflected signals in the first data and the second data. An input to the trained machine learning model may be based on the magnitude data and the phase data.

The one or more processing devices may be configured to use a classifier machine learning model to identify a type of the DUT. The classifier machine learning model may select the trained machine learning model based in the type of the DUT. The one or more processing devices may be configured to use a classifier machine learning model to identify a type of the DUT. The classifier machine learning model may select a second trained machine learning model based on the type of the DUT for determining electrical characteristics of a connection including the connection setup to the DUT. The one or more processing devices may be configured to execute the second trained machine learning model to determine the electrical characteristics of the connection. The electrical characteristics may include at least one of a capacitance or an inductance of the connection including the connection setup to the DUT.

An example method includes operations to train a machine learning model to determine a quality of a connection between a tester and a DUT. The method may include the following operations: transmitting first RF signals to a connection setup when the connection setup is in an open-ended configuration; receiving first reflections from the connection setup, where the first reflections are based on the first RF signals; transmitting second RF signals to the connection setup when the connection setup is connected to the DUT; receiving second reflections from the connection setup, where the second reflections are based on the second RF signals, and where the second reflections are associated with respective return loss contributions from the DUT; obtaining information about at least one of the DUT or the tester that performed the transmitting and receiving operations; and training the machine learning model based on the information, the first reflections, and the second reflections. The example method may include one or more of the following features, either alone or in combination.

The method may include performing the operations for at least one of: different types of DUTs or different instances of a same type of DUT. The method may include performing the operations for at least one of: different types of testers or different instances of a same type of tester. The method may include performing the operations for at least one of: different types of connection setups or different instances of a same type of connection setup. The method may include performing the operations for at least one of: different types of connections between the connection setup and the DUT or different instances of a same type of connection between the connection setup and the DUT. The machine learning model may include one or more machine learning models and may be configured also to classify the DUT and to characterize an electrical connection including the connection setup to the DUT. The machine learning model may include one or more of a neural network model or a large language model. One or more non-transitory machine-readable media may store instructions that are executable by one or more processing devices to implement a simulator configured to perform the method with or without any one or more of the foregoing features.

Any two or more of the features described in this specification, including in this summary section, may be combined to form implementations not specifically described in this specification.

At least part of the devices, systems, and processes described in this specification may be configured, controlled, and/or implemented by executing, on one or more processing devices, instructions that are stored on one or more non-transitory machine-readable storage media. Examples of non-transitory machine-readable storage media include read-only memory, an optical disk drive, memory disk drive, and random access memory. At least part of the devices, systems, and processes described in this specification may be configured, controlled and/or implemented using a computing system comprised of one or more processing devices and memory storing instructions that are executable by the one or more processing devices to perform various control operations. The devices, systems, and processes described in this specification may be configured, for example, through design, construction, composition, arrangement, placement, programming, operation, activation, deactivation, and/or control.

The details of one or more implementations are set forth in the accompanying drawings and the following description. Other features and advantages will be apparent from the description and drawings, and from the claims.

### DESCRIPTION OF THE DRAWINGS

FIG. 1 is a block diagram showing example S parameters for devices included in an example testing configuration.

FIG. 2 is a block diagram showing the testing configuration of FIG. 1 with different configurations of the connection setup and device under test (DUT).

FIG. 3 is a block diagram of an example test system.

FIG. 4 is a block diagram of the example test system in an open-ended configuration.

FIG. 5 is a block diagram of the example test system in a closed-ended configuration, in which the test system is connected to a DUT.

FIG. 6 is a block diagram of an example analyzer configured to use machine learning techniques to determine the quality of a connection between a test system and a DUT.

FIG. 7 is a block diagram of an example signal processing block that may be included in the example analyzer.

FIG. 8 is a graph showing example operation of filters included in the signal processing block.

FIG. 9 is a block diagram showing an example simulation of a connection between a test system and a DUT.

FIG. 10 is a circuit diagram representing an example connection point between a connection setup and a DUT.

FIG. 11 is a circuit diagram representing an example DUT.

FIG. 12 is a block diagram showing components of a radio frequency simulator used to train machine learning models.

FIG. 13 is a flowchart showing operations included in an example process for training machine learning models.

Like reference numerals in different figures indicate like elements.

### DETAILED DESCRIPTION

Test systems, such as automatic test equipment (ATE), are configured to test the operation of electronic devices referred to as devices under test (DUTs). Examples of DUTs that may be tested by a test system includes electronic devices such as transmitters or microprocessors, and system-level devices such as smartphones. The testing may include radio frequency (RF) testing to test RF components of the DUT. RF testing may occur over wired media, such as RF transmission lines or coaxial cables.

The quality of the RF connection between the test system and the DUT is a factor that influences the accuracy and reliability of the RF testing. The quality of the RF connection to the DUT can also affect RF testing outcomes. For example, in manufacturing, the quality of the connection to the DUT may impact the Cpk (process capability index) and yield rate. Low quality connections can decrease the quality of the RF testing and/or increase the cost of the RF testing.

The quality of the RF connection to the DUT can be degraded by mechanical vibration or variations and wear of an RF probe, which may be difficult to measure and to detect directly. In an example, the RF probe is the electrical connection between a DUT and an RF connection setup, which may be referred to herein as a “connection setup”. In some implementations, the connection setup includes the medium or media over which RF signals are sent including, but not limited to, transmission media and connectors between the test system and the DUT. Connection issues often are noticed only when those connection issues start to affect the RF testing results.

Return loss (RL) is a metric that may indicate the quality of an RF connection. In some examples, RL is a measurement of the power ratio of a signal reflected by a DUT and/or discontinuities in RF transmission lines or cables that are part of the RF connection to the DUT. Scattering parameters, called “S parameters”, characterize the behavior of an RF connection. Of the S parameters, the S11 parameter corresponds to the RL. The S11 parameter is a complex number having a magnitude and a phase. RL is usually expressed as the negative of the magnitude of the S11 parameter in decibels (dB). The smaller that the magnitude of the S11 parameter is, the greater the RL will be, and vice versa.

S11 parameter values for an RF connection between a test system and a DUT will be embedded with S11 parameter values of the DUT due to the RF connection between the connection setup and the DUT. As such, the S11 parameter value that is measured for an RF connection between a test system and a DUT will not be for the RF connection only. In other words, the S11 parameter value measured for an RF connection between a test system and a DUT is not an accurate representation of the RL of the connection setup, but rather includes a contribution from the DUT.

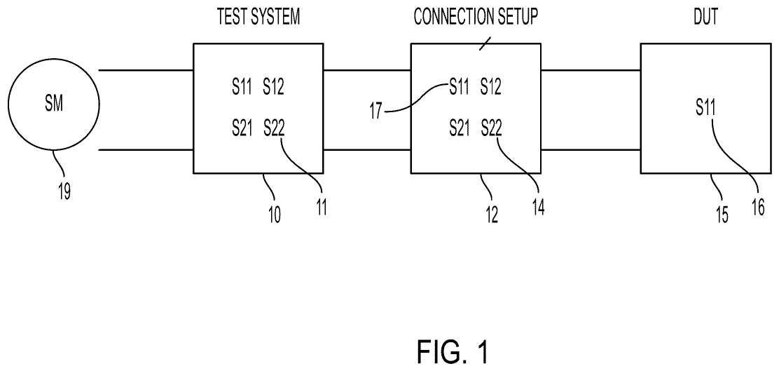

In this regard, FIG. 1 shows an example test system 10 having S parameters 11, a connection setup 12 having S parameters 14, and a DUT 15 having S11 parameter 16. The S parameters of test system 10, connection setup 12, and DUT 15 all have different values in some implementations. The S parameters of test system 10 may be known or determined. The challenge is to determine the value of S11 parameter 17 of connection setup 12 when what is available is a test system measurement Sm 19 made using connection setup 12 connected to DUT 15.

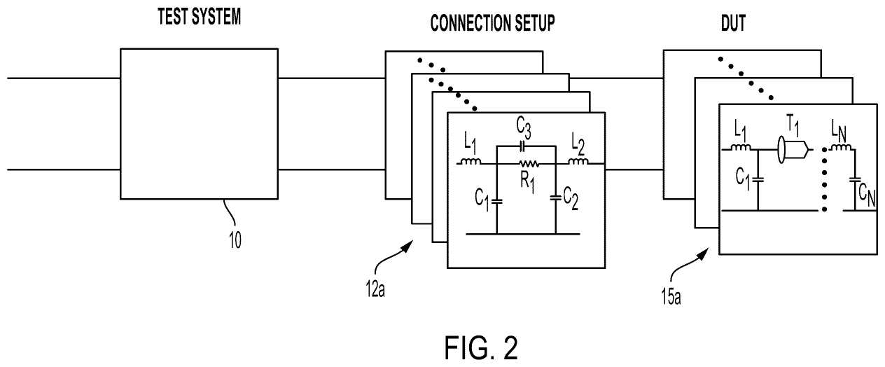

Referring to FIG. 2, the example systems and processes described herein determine the values of S11 parameters of test system 10 based on measurements of reflections of signals output to an open-ended connection setup, as described below. The problem then becomes to determine a circuit model for a connection setup and an S11 parameter value for that circuit model that fits Sm 19 (FIG. 1). The mathematical computations required to fit a circuit model to SM may be computationally prohibitive because they require searching multiple parameters and circuit configurations for multiple connection setups 12a and for multiple DUT configurations 15a.

Accordingly, the example systems and processes perform the circuit modeling and determine the quality of the RF connection—for example, the RL or S11 parameter value—between a test system and a DUT using machine learning (ML). Because ML is used, processes can quickly adapt to different types of DUTs by using S11 data for different DUTs and training an ML model. The systems and processes may leverage an RF simulator to generate a large and diverse training dataset that covers various test systems, connection setups, DUTs, and connection qualities, thus avoiding the need for collecting and labeling real data manually, which may be impractical in some cases.

The processes described herein may operate inside a test system or on a local computer. However, at least part of the processes, such as ML training, may be performed using a service that is external to the test system or local computer. For example, ML training may be performed using cloud computing.

An example system of the type described above includes a tester configured to test a DUT, and a connection setup, such as one or more RF transmission lines or coaxial cables, that is connectable to, and disconnectable from, the DUT. The tester is configured to transmit RF signals over the connection setup and to capture reflected signals from the connection setup that are based on the transmitted RF signals. One or more processing devices are configured to use a trained ML model to determine a quality of a connection, such as an RL or S11 parameter value of the connection setup, between the test system and the DUT based at least on the reflected RF signals.

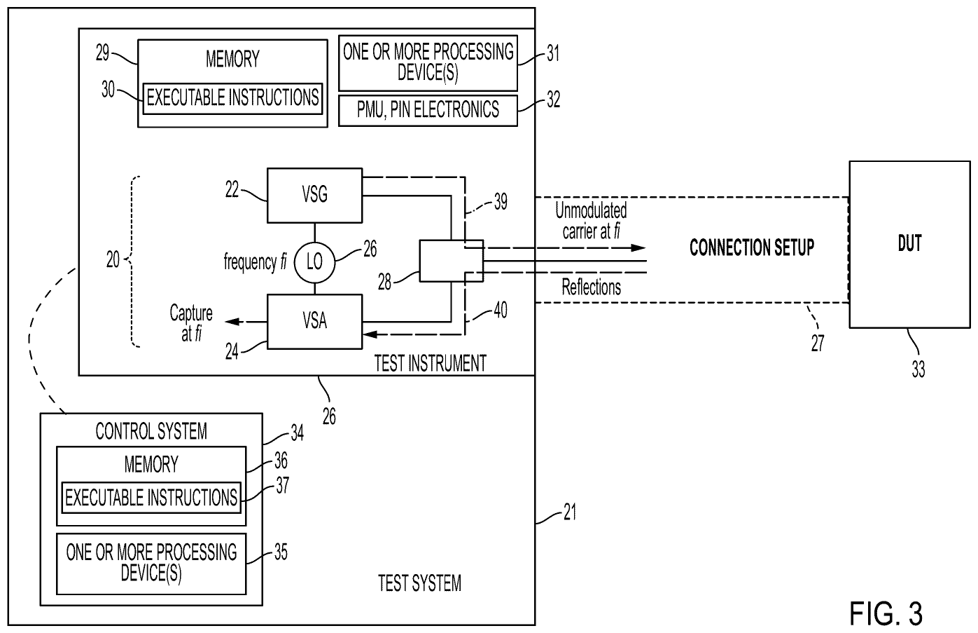

FIG. 3 shows components 20 of an example test system 21. In some implementations, components 20 includes vector signal generator (VSG) 22, vector signal analyzer (VSA) 24, and a local oscillator (LO) 25. Components 20 may form a vector network analyzer (VNA) and may be included in one or more test instruments 26 such as that described below. An example VNA is a device configured to obtain the magnitude and phase of an input signal at a given frequency, fi.

An example VSG 22 is a hardware device configured to generate signals and to output those signals over a connection setup 27 to DUT 33. An example connection setup may include, but is not limited to, RF transmission line(s), coaxial cable(s), connector(s), and/or other components that are connectable to, and disconnectable from, a DUT. The signals may be or include RF signals for testing the DUT or for testing the quality of connection setup 27.

An example VSA 19 is a hardware device configured to receive signals from connection setup 27 and to identify the signals by measuring parameters, such as a magnitude and/or a phase, of the received signals. The received signals may be full or partial reflections of the RF signals transmitted by VSG 22. For example, VSA 24 may be configured to compare a received signal to one or more reference signals or to one or more thresholds to identify one or more parameters for the received signal.

An example LO 26 is a hardware device that feeds up and down conversion mixer circuitry used to up and down convert frequencies between the VSA or VSG and a combiner circuit 28. In some implementations, LO 26 may be a separate component or may be incorporated into VSG 22 or VSA 24.

In some implementations, VSA 24, VSG 22, and LO 26 may be separate hardware devices. In some implementations, VSA 24, VSG 22, and LO 26 may be combined into a single hardware device. In some implementations, VSA 24, VSG 22, and LO 26 may be implemented using one or more semiconductor devices such as transistors, diodes, and/or integrated circuits. In some implementations, VSA 24, VSG 22, and LO 26 may be implemented using one or more processing devices, such as those described herein, that are configured to execute instructions stored in memory to implement VSA, VSG, and LO functions. In some implementations, VSA 24, VSG 22, and LO 26 may be implemented using a combination of one or more semiconductor devices and one or more processing devices.

Combiner circuit 28 or other device may be configured to route signals between VSA 22, VSG 24, and devices that are connected to, and external to, test system 21. Combiner circuity may be integrated into the same device or devices as VSA 24, VSG 22, and LO 26 or combiner circuit may be a separate hardware device.

VSA 24, VSG 22, LO 26, and combiner circuit 28 may be part of test instrument 26, which is configured to test DUTs, such as those described herein. An example test instrument is a hardware device that may include one or more processing devices 31, components 20 of FIG. 3, and memory 29 storing instructions 30 that are executable by the one or more processing devices 31. Test instrument 26 may also include test electronics such as a parametric measurement unit (PMU) and/or pin electronics (PE) 32.

Test instrument 26 may be configured—for example, programmed—to output test signals to test an RF connection setup to a DUT. For example, processing device(s) 31 may also be configured to control components 20 contained in test instrument 26 based on execution of the instructions 30 stored in memory 29. In some implementations, test instrument 26 may be configured to determine the quality of an RF connection between a test system and a DUT using ML techniques as described herein. Test instrument 26 may also be configured—for example, programmed—to output test signals to test a DUT via a connection setup. The test signals to test the DUTs may be or include commands, instructions, data, parameters, variables, test vectors, and/or any other information designed to elicit response(s) from the DUT. Test instrument 26 may be configured to receive responses to the test signals and to analyze the responses to determine whether the DUT passed for failed testing. Test system 21 may include a control system 34. Control system 34 may include one or more processing devices 35 and memory 36 storing instructions 37 that are executable by the one or more processing devices 35 to perform various functions, including those listed below. In some implementations, control system 34 may control operation of test instrument 26, including components 20, as part of a testing process for determining the quality of the RF connection between the test system and a DUT. In some implementations, control system 34 may be configured to use measurements from test instrument 26 determine the quality of an RF connection between a test system and a DUT using the ML techniques.

In some implementations, the test system or a component thereof that performs testing may be referred to as a “tester. In some implementation, the test instrument or a component thereof that performs testing functions may be referred to as a “tester”.

In an example operation, VSG 22 is controllable by test instrument 26 or control system 34 to transmit an unmodulated carrier signal 39 to connection setup 27. VSA 24 is controllable by test instrument 26 or control system 34 to capture data representing a reflection 40 of at least part of the unmodulated carrier signal for each of multiple frequencies, fi, in reflection 40. The captured data may include the magnitude and phase of the reflected signal at each frequency, fi. The captured data constitutes the Sm measurements noted above. The test system repeats these operations for a predefined number of frequency points with a predefined frequency range and eventually collects a data set as a vector of frequencies. The predefined number of frequency points may be on the order of hundreds or thousands of frequencies in some implementations. The vector thus includes data for one or more reflected signals at multiple different frequencies. The test system generates a data file based on the vector.

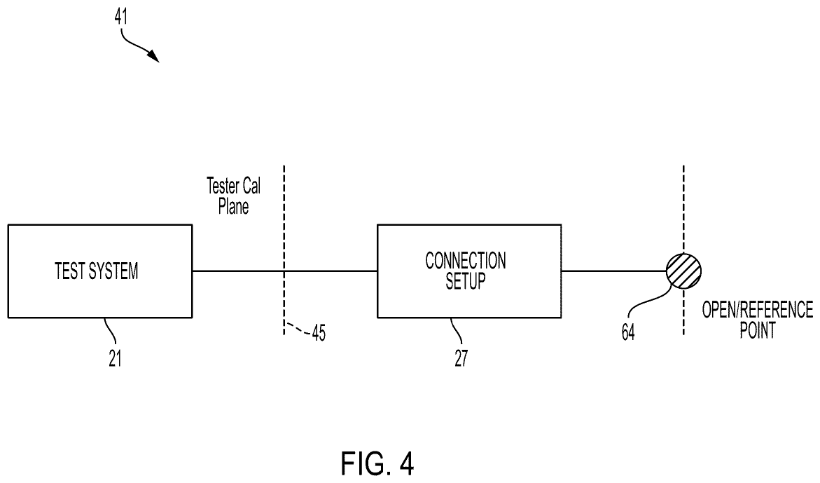

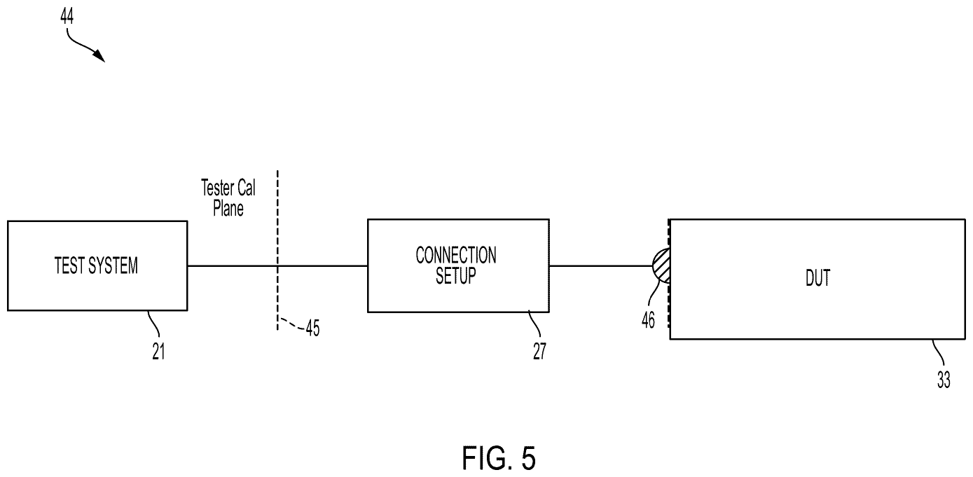

VSG 22 and VSA 24 are controllable to generate two data files using the operations described above. FIGS. 4 and 5 show different test system configurations 41 and 44, respectively, used to generate the two data files. FIG. 4 shows a test configuration in which connection setup 27—for example, RF transmission line(s) and/or coaxial cable(s)—is open-ended. Open-ended in this context means that connection setup is not connected to a DUT or to any other device. FIG. 5 shows a test configuration in which connection setup 27 is connected to a DUT. As shown in both FIGS. 4 and 5, the test system is calibrated to calibration plane 45. In some implementations, the measurements made by test system 21 may be made relative to this calibration plane. In some implementations, calibration information for this plane is included in each data file and is used to remove, from data in each data file, all or some connection quality contributions from the test system.

To capture the first data file, called “data file #1”, VSA 24 and VSG 22 are controlled to operate as described above using the test configuration of FIG. 4. VSG 22 transmits first RF signals over connection setup 27 and VSA measures reflections of those first RF signals from the open end of the connection setup. Data file #1 includes magnitude and phase measurements of the reflected first RF signals at multiple frequency points, fi. Data file #1 may also include the magnitude and phase of the transmitted first RF signals at the multiple frequency points, fi, along with identity of the test system, such as its type, manufacturer, model number, or the like. The data from data file #1 is used to detect the location of the open (or reference) point 64 of FIG. 4 in the time domain. In some implementations, the open (or reference) point is the connection point 46 (FIG. 5) to which a DUT would be connected during testing.

To capture the second data file, called “data file #2”, VSA 24 and VSG 22 are controlled to operate as described above using the test configuration of FIG. 5. VSG 22 transmits second RF signals over connection setup 27 and VSA measures reflections of those second RF signals. Ones of the second RF signals may be identical respective ones of the first RF signals. Data file #2 includes magnitude and phase measurements of the reflected second RF signals at multiple frequency points, fi. Data file #2 may also include the magnitude and phase of the transmitted second RF signals at the multiple frequency points fi, along with identity of the test system, such as its type, manufacturer, model number, or the like. The data files may be processed by an analyzer to determined the connection quality/RL/S11 parameter value(s) of connection setup 27.

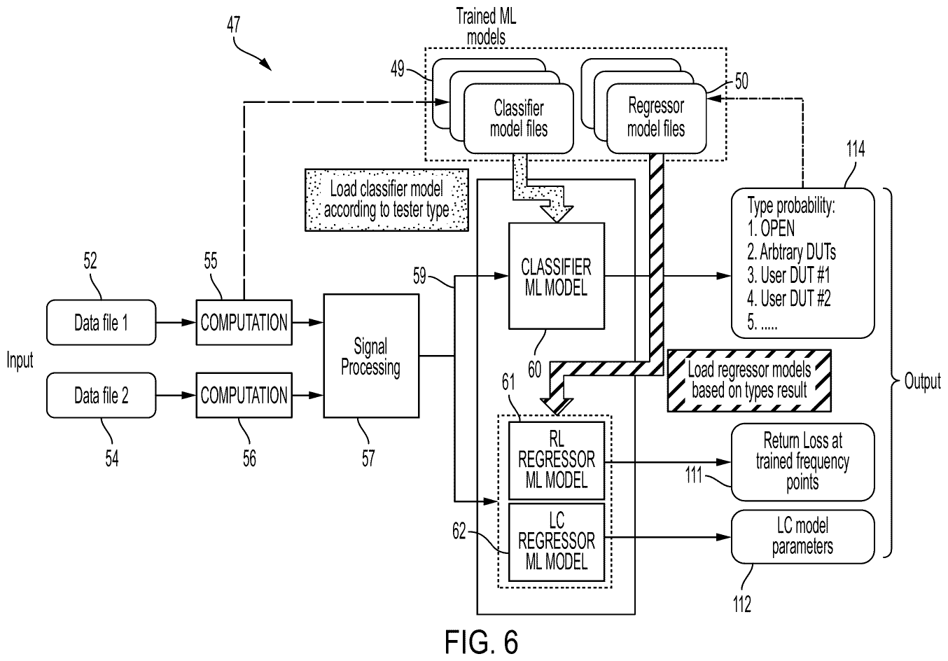

Components of example analyzer 47 are shown in FIG. 6. Analyzer 47 may be implemented in software, e.g., executable instructions, run by processing device(s) on test instrument 26, on control system 34, or external to test system 21.

In this example, analyzer 47 includes one or more classifier ML models 49 and one or more regressor ML models 59. Classifier ML models 49 have been trained to classify a type of DUT with its RF connection in a test system configuration, such those shown in FIGS. 4 and 5. Examples, including “open”, meaning that no DUT is connected to the connection setup; “arbitrary DUT”, meaning that the DUT is not a type of DUT known to analyzer 47; and DUT #1, DUT #2, etc., where DUT #1, DUT #2, etc. refer to predefined DUTs, the identities of which are programmed into analyzer 47.

Regressor ML models 50 include at least two different types of regressor ML models. Some of the regressor ML models 50 have been trained to determine the RL of the RF connection between a test system and a DUT, which has the RL contribution from the DUT removed. These are referred to as RL regressor models. Some of the regressor ML models 50 have been trained to determine electrical characteristics of the RF connection between the test system and the DUT. These are referred to as lumped-circuit (LC) regressor models. In this regard, the electrical characteristics may be expressed in terms of inductance (L), capacitance (C), resistance (R), delays (D), and the like concentrated at a single point and their behavior can be described by idealized mathematical models. In some implementations, the electrical characteristics may be modeled using a circuit having one or more inductors, one or more capacitors, one or more resistors, one or more delay elements, and/or other passive circuit components.

Analyzer 47 is configured to receive data file #1 52 and data file #2 54. Analyzer may be configured to perform a mathematical computation 55 and 56 on each respective data file based on calibration data for the test system. The mathematical computation may be based on 1-port VNA calibration. For example, the data included in data file #1 52 and data file #2 54 may be processed to remove an RL contribution from the test system 21 itself from the data in each data file. Analyzer 47 is also configured to select one of ML models 49 to use as a classifier ML model 60 based on the information about the identity of the test system 21 from one of the data files, such as data file #1.

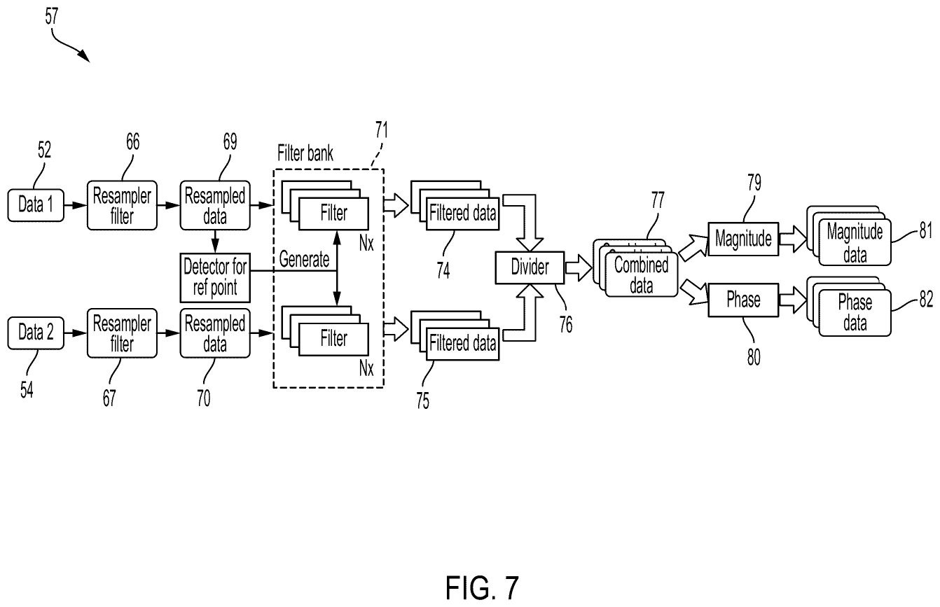

Signal processing block 57 of analyzer 47 is configured to receive the processed data from data file #1 52 and data file #2 54 and to determine magnitude and phase vectors based on the reflected signals using the data in those data files. Operations of signal processing block 57 to determine these magnitude and phase vectors are described below with respect to FIG. 7.

The output 59 of signal processing block passes to classifier ML model 60. Classifier ML model 60 is executed to determine the probability that DUT 33 (e.g., FIGS. 3, 5) is “arbitrary”, “DUT #1, or “DUT #2”, etc. or there is no DUT (e.g., FIG. 4), in which case the DUT is characterized as “open”. This information 114 may be output from analyzer 47 to a user. In some implementations, analyzer 47 is configured to use the identity of the DUT determined by classifier ML model 60 to have the highest probability to select at least two regressor models. In this example, the regressor models selected include an RL regressor model 61 and an LC regressor model 62. Analyzer 47 is also configured to use the magnitude and phase vectors output by signal processing block 57 as input to RL regressor model 61 and LC regressor model 62.

RL regressor model 61 has been trained to provide, based on the magnitude and phase vectors output by signal processing block 57, the RL or S11 parameters of the connection setup 27 at one or more predefined frequency points absent an RL or S11 parameter contribution from DUT 33 (FIGS. 3, 5). For example, in the test system configuration of FIG. 5, RL regressor model 61 is configured to output the RL or S11 parameter values 111 of the connection setup 27 between test system 21 and connection point 46. LC regressor model 62 is configured to provide, based on the magnitude and phase vectors output by signal processing block 57, to output parameters 112 such as inductance, capacitance, resistance, and so forth that model the connection setup 27 between test system 21 and the connection point 46 to the DUT. In some implementations, LC regressor model 62 may be configured to output a textual definition of, or a graphical display of, a circuit configuration containing passive circuit elements such as those described herein that model the connection setup.

FIG. 7 is a block diagram of an example implementation of signal processing block 57. Signal processing block 57 may be implemented in software, e.g., executable instructions, run by one or more processing device(s) on test instrument 26, on control system 34, and/or external to test system 21.

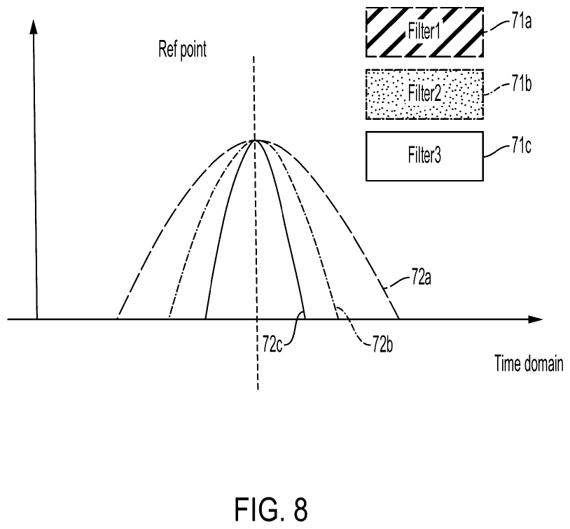

Signal processing block 57 is configured to receive data file #1 52 and data file #2 54. The data from data file #1 52 and data file #2 54 is resampled by resampler filters 66 and 67, respectively, along frequency points to have the same feature size (e.g., frequency points size) as analyzer 47 and to thereby produce resampled data 69 and 70. A filter bank 71 is generated having K (where K is an integer greater than one) filters, with each filter having a different time window size (resolution), as shown in FIG. 8. More specifically, in the example of FIG. 8, example filters 71a, 71b, 71c from the filter bank have respective resolutions 72a, 72b, 72c to attenuate the data from data file #1 52 and data file #2 54 in the time domain. The filters attenuate the data from data file #1 52 and data file #2 54 to focus the data in each data file on the connection point 46 (FIG. 5) to DUT 33.

Referring back to FIG. 7, in this example, each filter outputs one vector, resulting in six output vectors 74, 75 for the three-filter example shown in FIG. 7. It is noted that the signal processing block 57 may contain more than three filters or fewer than three filters. These output vectors are referred to as filtered data in FIG. 7. Each of the six vectors has the same size. To remove the effects of path loss on the data in the vectors 74, 75, elements of vectors 74 based on data file #1 are divided (76) by respective elements of vectors 75 based on data file #2, or the elements of vectors 75 based on data file #2 are divided by respective elements of vectors 74 based on data file #1. Path loss, in this context, may include the reduction in power density of a signal as the signal travels along connection setup 27. The resulting data 77 is combined data comprised of N vectors each with M elements, where M and N are each integers greater than one. The combined data 77 having N vectors each with M features then passes to magnitude calculator 79 and phase calculator 80. The output of magnitude calculator 79 is magnitude data 81 comprised of N vectors each with M features. The output phase calculator 80 is phase data 82 comprised of N vectors each with M features.

In some implementations, the ML models may be or include a 1-D multiple-layer convolutional neural network. The network may be trained independently for each classifier ML model and regressor ML model, which may then be stored and loaded into a computing system as separate ML model files. The input data size may be 2N vectors, with each vector having M features, such as the magnitude and phase vectors described above. In some implementations, the ML models may be or include large language models or any other neural network models.

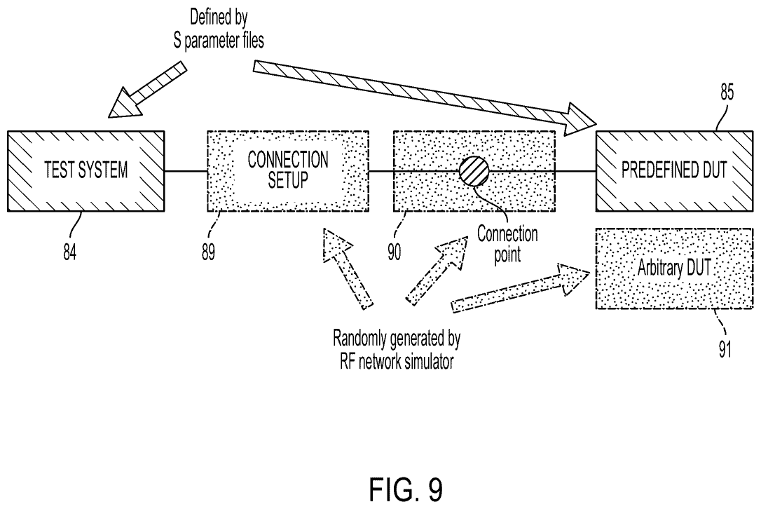

Training of the ML models is described with respect to FIGS. 9 to 13. The training may be performed on a computing system that is part of the test system or the training may be performed on a computing system that is external to the test system. For example, the training may be performed on a cloud computing system. The resulting trained ML models may then be stored in any memory on the test system.

The techniques described herein may use an RF simulator to generate a training dataset that covers various types of connection setups and connection qualities. An example RF simulator is a computer program that simulates test systems, connection setups, DUTs, and RF connections among these components. The RF simulator may be executed on a computing system that is part of the test system or the RF simulator may be executed on a computing system that is external to the test system. For example, the RF simulator may be executed on a cloud computing system.

FIG. 9 shows a block diagram of an example simulation, which may be generated by the RF simulator, of a test system configuration containing test system 84 and DUT 85, which may be versions of test system 21 and DUT 33, respectively. In this regard, S parameter files may be stored in the RF simulator for various types of testers and DUTs. For example, S parameter files may be stored for testers having different functionality, for testers from different manufacturers, for different models of the same tester from the same manufacturer, for different instances of the same model of tester, and so forth. For example, S parameter files may be stored for DUTs having different functionality, for DUTs from different manufacturers, for different models of the same DUT from the same manufacturer, for different instances of the same model of a DUT, and so forth. Blocks 89, 90, and 91 represent a simulated connection setup, a simulated DUT connection point, and a simulated arbitrary DUT, respectively, all of which may be examples of those same elements described above.

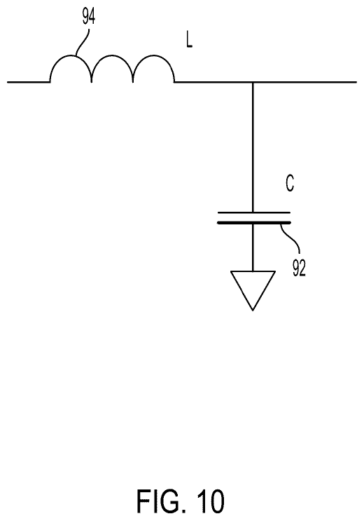

In this example, the RF simulator is configured to randomly generate different combinations of test systems, connection setups, reference points, and DUTs, and to train ML models based on these combinations and the stored S parameter files for the test system(s) and the DUT(s). In some implementations, the connection setup is randomly generated to include different coaxial cables, transmission lines, attenuators, and/or connections. In some implementations, the connection setup includes different types of connection setups or different instances of the same type of connection setup. Connection point 90 to the DUT may be modeled as shunt capacitance (C) 92 and inductance (L) 94 as shown in FIG. 10 or any other appropriate circuit configuration. The capacitance and inductance values may be randomly selected from a distribution that is designed to provide a close-to-uniform distribution for regression labels.

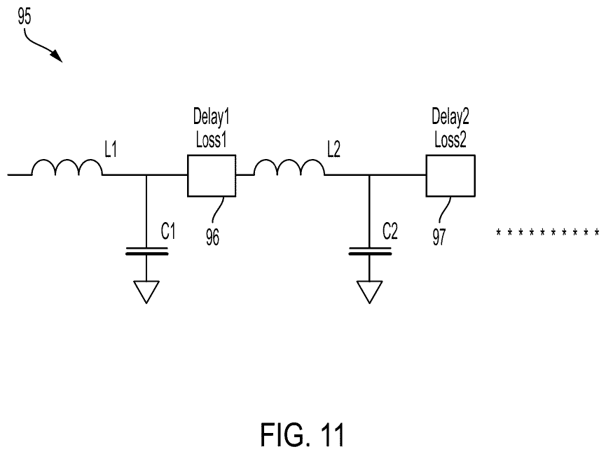

DUT 85 may be defined by the user input S11 data files. DUT 85 may be defined using a single S11 parameter value, or multiple S11 data files. In the case of multiple S11 data files for one predefined DUT type, the RF simulator will pick one S11 parameter value randomly with equal probability for one generated data sample. The arbitrary DUT 91 is a model for a DUT type not classified as any predefined DUT type. The model 95 for that DUT may be a series of inductances (e.g., L₁, L₂, etc.) and capacitances (e.g., C₁, C₂, etc.) combined with extra losses and delays 96, 97, etc. as shown in FIG. 11. Other appropriate circuit configurations may be used to model the DUT. All the parameters of the model may be randomly selected.

The training dataset for each classifier ML model or regressor ML model may be generated independently. For the classifier ML model, a data label is generated by the DUT type used in the simulated connection setup 89. For the RL regressor ML model, the data label is generated by the S11 data of the DUT connection point model 90. For the LC regressor ML model, the data label is generated based on the capacitance and inductance value used in the DUT connection mode 901.

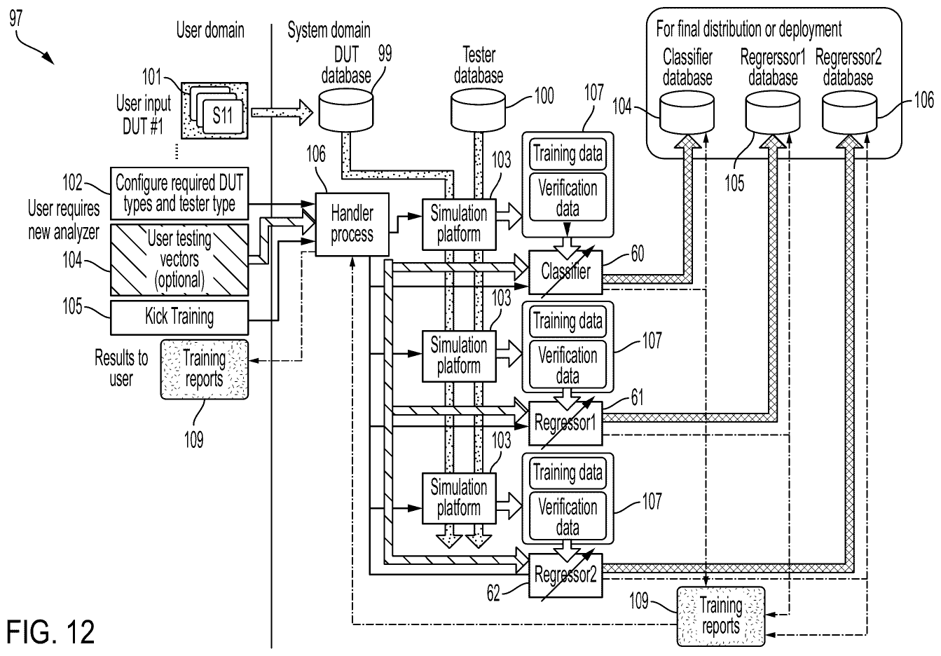

FIG. 12 shows an example RF simulator 97 for generating the trained ML models. RF simulator 97 may be implemented in software, e.g., executable instructions, run by processing device(s), e.g., on the control system or external to test system 21 such as in a cloud computing environment.

RF simulator 97 may include a DUT database 99 containing S11 parameter values for various DUTs and a tester database 100 containing S11 parameter values for various test systems and information about the configuration of those test systems. In some implementations, a user can input S11 parameter values 101 for a DUT on which the ML models are to be trained. In some implementations, a user can input information 102 to configure a DUT on which the ML models are to be trained, such as a circuit model. In some implementations, a user can input test vectors 104 for training. The user may also provide an input 105 to begin or “kick” training. Handler process 106 is configured to select information from DUT database 99 and tester database 100 based on user input 101, 102, and/or 104. Code 103 (simulation platform) executing in RF simulator 97 generates training and verification data 107 based on the data from the DUT database 99, the tester database 100, and user input 101, 102, and/or 104. The training data may include simulated measurements, Sm, of reflected signals as described herein with respect to FIG. 3, for example. The verification data may include expected S11 values given a simulated test configuration.

RF simulator 97 generates the trained classifier ML model 60, RL regressor ML model 61, and LC regressor ML model 62, using the training data and stores the classifier ML model 60, RL regressor ML model 61, and LC regressor ML model 62 in respective databases 104, 105, and 106. The classifier ML model 60, RL regressor ML model 61, LC RL regressor ML model 62 may be distributed to analyzer 47 from databases 104, 105, 106 or accessed from databases 104, 105, 106 by analyzer 47. In some implementations, more than, or fewer than, three ML models may be used. For example, functionality for two of the ML models may be combined into single ML model or functionality for a single model may be split into two ML models.

In some implementations, RF simulator 97 tests the trained classifier ML model, RL regressor ML model, and LC regressor model using analyzer 47 and the verification data set. The system generates one or more training reports 109 based on these tests. The training reports 109 may be output to a user to allow the user to determine the accuracy of the trained ML models prior to deployment on a test system.

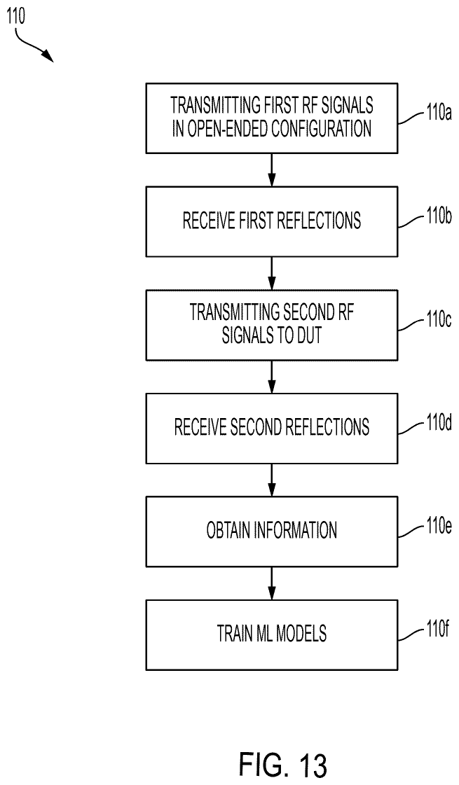

Referring to FIG. 13, RF simulator 97 may be configured to perform the operations of example process 110 to generate the training data. Process 110 includes transmitting (110a) first RF signals to a connection setup when the connection setup is in an open-ended configuration. This operation may be performed by a simulated VSG and connection setup, similar to that shown in FIG. 3. Process 110 includes receiving (110b) first reflections from the connection setup. The first reflections ae based on the first RF signals; for example, the first reflections may contain all or part of the first RF signals. This operation may be performed by a simulated VSA and connection setup, similar to that in FIG. 3, to generate a data file #1. Process 110 includes transmitting (110c) second RF signals to the connection setup when the connection setup is connected to the DUT. This operation may be performed by a simulated VSG and connection setup, similar to that in FIG. 3. Process 110 includes receiving (110d) second reflections from the connection setup. The second reflections are based on the second RF signals and are associated with respective RL contributions from the DUT. This operation may be performed by a simulated VSA and connection setup, similar to that in FIG. 3, to generate a data file #2. Process 110 includes obtaining (110e) information about at least one of the DUT (e.g., DUT S11 parameter(s)) or a tester (e.g., the tester S11 parameter(s)) that performed the transmitting and receiving operations. Operations 110a to 110e may be repeated hundreds, thousands, or millions of times to obtain training data for the ML models, such as the classifier ML model, the RL regressor ML model, and the LC regressor model. The result of performing operations 110a to 110e multiple times generates a training data set. The ML models may be trained (110f) based on this training data set for different types of DUTs and/or different instances of a same type of DUT; for different types of testers and/or different instances of a same type of tester; and/or for different types of connection setups between the test system and the DUT, and/or different instances of a same type of connection setup between the test system and the DUT.

All or part of the systems and processes described herein including but not limited to process 110 and its modifications may be implemented, configured and/or controlled at least in part by one or more computers using one or more computer programs tangibly embodied in one or more information carriers, such as in one or more non-transitory machine-readable storage media. A computer program can be written in any form of programming language, including compiled or interpreted languages, and it can be deployed in any form, including as a stand-alone program or as a module, part, subroutine, or other unit suitable for use in a computing environment. A computer program can be deployed to be executed on one computer or on multiple computers at one site or distributed across multiple sites and interconnected.

Actions associated with implementing, configuring, or controlling the test system and processes described herein can be performed by one or more programmable processors executing one or more computer programs to control or to perform all or some of the operations described herein. All or part of the test systems and processes can be implemented, configured, or controlled by special purpose logic circuitry, such as, an FPGA (field programmable gate array) and/or an ASIC (application-specific integrated circuit) or embedded microprocessor(s) localized to the instrument hardware.

Processors suitable for the execution of a computer program include, by way of example, both general and special purpose microprocessors, and any one or more processors of any kind of digital computer. Generally, a processor will receive instructions and data from a read-only storage area or a random access storage area or both. Elements of a computer include one or more processors for executing instructions and one or more storage area devices for storing instructions and data. Generally, a computer will also include, or be operatively coupled to receive data from, or transfer data to, or both, one or more machine-readable storage media, such as mass storage devices for storing data, such as magnetic, magneto-optical disks, or optical disks. Non-transitory machine-readable storage media suitable for embodying computer program instructions and data include all forms of non-volatile storage area, including by way of example, semiconductor storage area devices, such as EPROM (erasable programmable read-only memory), EEPROM (electrically erasable programmable read-only memory), and flash storage area devices; magnetic disks, such as internal hard disks or removable disks; magneto-optical disks; and CD-ROM (compact disc read-only memory) and DVD-ROM (digital versatile disc read-only memory).

All examples described herein are non-limiting.

In the description and claims provided herein, the adjectives “first”, “second”, “third”, and the like do not designate priority or order unless context suggests otherwise. Instead, these adjectives may be used solely to differentiate the nouns that they modify.

Any mechanical or electrical connection herein may include a direct physical connection or an indirect physical connection that includes one or more intervening components. A connection between two electrically conductive components includes an electrical connection unless context suggests otherwise. The signals described herein are electrical signals unless context suggests otherwise.

Elements of different implementations described may be combined to form other implementations not specifically set forth previously. Elements may be left out of the systems described previously without adversely affecting their operation or the operation of the system in general. Furthermore, various separate elements may be combined into one or more individual elements to perform the functions described in this specification.

Other implementations not specifically described in this specification are also within the scope of the following claims.

What is claimed is:

1. A system comprising:
a tester configured to test a device under test (DUT);
a connection setup that is connectable to, and disconnectable from, the DUT;
wherein the tester is configured to transmit radio frequency (RF) signals over the connection setup and to capture reflected signals from the connection setup, the reflected signals being based on the RF signals; and
one or more processing devices configured to use a trained machine learning model to determine a quality of a connection between the test system and the DUT based on the reflected signals.

2. The system of claim 1, wherein the tester is configured to capture first data when the connection setup is disconnected from the DUT, the first data being based on first ones of the reflected signals; and
wherein the tester is configured to capture second data when the connection setup is connected to the DUT, the second data being based on second ones of the reflected signals.

3. The system of claim 2, wherein the second ones of the reflected signals are each associated with a respective return loss, the respective return loss including a return loss contribution from the DUT.

4. The system of claim 3, wherein determining the quality of the connection comprises determining a return loss of the connection setup when the connection setup is connected to the DUT minus the return loss contribution from the DUT.

5. The system of claim 3, wherein the one or more processing devices are configured to process data based on the reflected signals in the first data and the second data to remove a return loss contribution from the tester.

6. The system of claim 5, wherein, following processing, the one or more processing devices are configured to resample data based on the reflected signals in the first data and the second data.

7. The system of claim 6, wherein, following resampling, the one or more processing devices are configured to filter data based on the reflected signals in the first data and the second data to attenuate representations of the reflected signals in the first data and the second data.

8. The system of claim 7, wherein, following filtering, the one or more processing devices are configured to process data based on the reflected signals in the first data and the second data to discount, in each signal, a path loss associated with the connection setup and thereby produce combined data.

9. The system of claim 8, wherein the combined data comprises magnitude data and phase data that is based on the reflected signals in the first data and the second data, where an input to the trained machine learning model is based on the magnitude data and the phase data.

10. The system of claim 1, wherein the one or more processing devices are configured to use a classifier machine learning model to identify a type of the DUT; and
wherein the classifier machine learning model selects the trained machine learning model based in the type of the DUT.

11. The system of claim 1, wherein the one or more processing devices are configured to use a classifier machine learning model to identify a type of the DUT;
wherein the classifier machine learning model selects a second trained machine learning model based on the type of the DUT for determining electrical characteristics of a connection including the connection setup to the DUT; and
wherein the one or more processing devices are configured to execute the second trained machine learning model to determine the electrical characteristics of the connection.

12. The system of claim 11, wherein the electrical characteristics comprise at least one of a capacitance or an inductance of the connection including the connection setup to the DUT.

13. A method of training a machine learning model that determines a quality of a connection between a tester and a device under test (DUT), the method comprising the following operations:
transmitting first RF signals to a connection setup when the connection setup is in an open-ended configuration;
receiving first reflections from the connection setup, the first reflections being based on the first RF signals;
transmitting second RF signals to the connection setup when the connection setup is connected to the DUT;
receiving second reflections from the connection setup, the second reflections being based on the second RF signals, the second reflections being associated with respective return loss contributions from the DUT;
obtaining information about at least one of the DUT or the tester that performed the transmitting and receiving operations; and
training the machine learning model based on the information, the first reflections, and the second reflections.

14. The method of claim 13, wherein the method comprises performing the operations for at least one of: different types of DUTs or different instances of a same type of DUT.

15. The method of claim 13, wherein the method comprises performing the operations for at least one of: different types of testers or different instances of a same type of tester.

16. The method of claim 13, wherein the method comprises performing the operations for at least one of: different types of connection setups or different instances of a same type of connection setup.

17. The method of claim 13, wherein the method comprises performing the operations for at least one of: different types of connections between the connection setup and the DUT or different instances of a same type of connection between the connection setup and the DUT.

18. The method of claim 13, wherein the machine learning model comprises one or more machine learning models and is configured also to classify the DUT and to characterize an electrical connection including the connection setup to the DUT.

19. The method of claim 13, wherein the machine learning model comprises one or more of a neural network model or a large language model.

20. One or more non-transitory machine-readable media storing instructions that are executable by one or more processing devices to implement a simulator configured to perform the method of claim 13.
